(19) United States
(12) Patent Application Publication
(10) Pub. No.: US 2017/0236541 A1
(43) Pub. Date: Aug. 17, 2017

(54) HYBRID STORAGE DEVICE HAVING A HEATER IN A HEAD AND METHOD OF OPERATING THE SAME

(71) Applicant: KABUSHIKI KAISHA TOSHIBA, Tokyo (JP)

(72) Inventors: Fumitoshi HIDAKA, Yokohama Kanagawa (JP); Masatoshi AOKI, Yokohama Kanagawa (JP); Itaru KAKIKI, Yokohama Kanagawa (JP)

(21) Appl. No.: 15/233,690

(22) Filed: Aug. 10, 2016

(30) Foreign Application Priority Data
Feb. 16, 2016 (JP) 2016-027370

(51) Int. Cl. G11B 5/60; G11C 16/10; G06F 3/06

(52) U.S. Cl. CPC G11B 5/607; G06F 3/061; G06F 3/0629; G06F 3/0655; G11C 16/10; G06F 3/0685; G06F 2212/217

(57) ABSTRACT

A storage device includes a disk, a head configured to carry out data writing and data reading with respect to the disk, and including a heater that generates heat to cause the head to thermally expand towards the disk, a non-volatile semiconductor memory, and a controller configured to set an amount of expansion of the head, based on data read from the disk during a predetermined period of time after the storage device has been turned on, and write data from a host in the disk or the non-volatile semiconductor memory during the predetermined period of time, based on the amount of expansion.

### CROSS-REFERENCE TO RELATED APPLICATION

This application is based upon and claims the benefit of priority from Japanese Patent Application No. 2016-027370, filed on Feb. 16, 2016, the entire contents of which are incorporated herein by reference.

### FIELD

Embodiments described herein relate generally to a storage device and a method of operating the same.

### BACKGROUND

A storage device of one type includes multiple types (for example, two types) of non-volatile memory media of which access speeds and memory capacities are different from each other. A hybrid drive is known as such a storage device. The hybrid drive generally includes a first non-volatile memory medium and a second non-volatile memory medium with a slower access speed and larger storage capacity than the first non-volatile memory medium.

A magnetic disk which is used for, for example, a hard disk drive (HDD) can be used as the second non-volatile memory medium. It is known that characteristics of the HDD during a period of time after rotation of the magnetic disk has been started, is different from those after the period.

### DESCRIPTION OF THE DRAWINGS

FIG. 1 illustrates a configuration of a storage device according to an embodiment.

FIG. 2A schematically illustrates a disk and a head when a heater is not operated, and FIG. 2B schematically illustrates the disk and the head when the heater is operated.

FIG. 3 is a flowchart illustrating an operation for setting protrusion amount of the head.

FIG. 4 is a flowchart illustrating a processing operation at the time of data writing.

### DETAILED DESCRIPTION

One embodiment provides a storage device with higher reliability.

In general, according to an embodiment, a storage device includes a disk, a head configured to carry out data writing and data reading with respect to the disk, and including a heater that generates heat to cause the head to thermally expand towards the disk, a non-volatile semiconductor memory, and a controller configured to set an amount of expansion of the head, based on data read from the disk during a predetermined period of time after the storage device has been turned on, and write data from a host in the disk or the non-volatile semiconductor memory during the predetermined period of time, based on the amount of expansion.

In the present disclosure, a plurality of expressions may be used for several elements. These expressions are merely an example, and do not deny that the aforementioned elements are described by other expressions. In addition, elements for which a plurality of expressions is not used may be described by different expressions.

In addition, the drawings are schematic, and a relationship between a thickness and a planar dimension, a ratio between thicknesses of each layer, or the like can be different from actuality. In addition, portions of which dimensional relationships and dimensional ratios are different from each other may be included in the drawings.

### First Embodiment

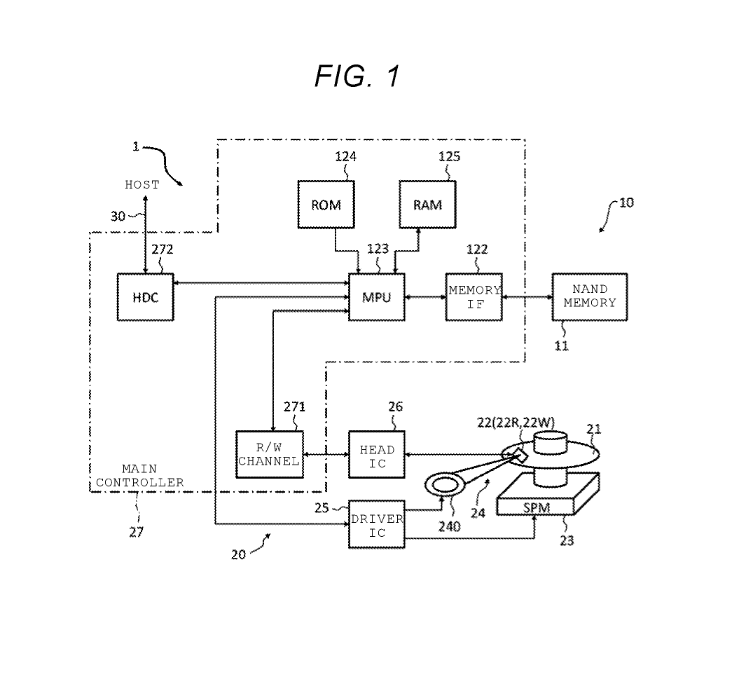

FIG. 1 illustrates a configuration of a storage device 1 according to the present embodiment. The storage device 1 according to the present embodiment is, for example, a hybrid drive. The hybrid drive includes a non-volatile memory medium (that is, a first non-volatile memory medium and a second non-volatile memory medium) of multiple types, for example, two types of which access speed and storage capacity are different from each other. In the present embodiment, the storage device 1 will be described as a hybrid drive 1.

In the present embodiment, a magnetic disk medium (hereinafter, referred to as a disk) 21 is used as the first non-volatile memory medium, and a NAND flash memory (hereinafter, referred to as a NAND memory) 11 is used as the second non-volatile memory medium. The disk 21 has slower access speed and larger storage capacity than the NAND memory 11.

The hybrid drive 1 illustrated in FIG. 1 includes a semiconductor drive unit 10 such as a solid state drive (SSD), and a hard disk drive unit (hereinafter, referred to as a HDD) 20. The semiconductor drive unit 10 includes at least the NAND memory 11 and a memory IF 122 included in a main controller (control unit) 27.

In the hybrid drive 1, the NAND memory 11 is used for various purposes. The NAND memory 11 is used for a performance increase of the hybrid drive 1, a stable write operation when the hybrid drive 1 vibrates, a fast start-up of the hybrid drive 1, or the like.

The main controller 27 controls access to the NAND memory 11 or the disk 21 according to an access request (for example, write request or read request) from a host device (hereinafter, referred to as a host). In the present embodiment, the NAND memory 11 is used as a cache (cache memory) for fast access to the hybrid drive 1, for example, that stores data which were recently accessed by the host. The host uses the hybrid drive 1 illustrated in FIG. 1 as a storage device for itself.

The main controller 27 includes a large scale integration (LSI) circuit of one chip in which multiple elements are integrated. The main controller 27 includes at least a memory interface controller (hereinafter, referred to as a memory IF) 122, a microprocessor unit (MPU) 123, a read only memory (ROM) 124, a random access memory (RAM) 125, a read/write (R/W) channel 271, and a hard disk controller (HDC) 272.

The memory interface (first interface controller) 122 is connected to the NAND memory 11, and accesses the NAND memory 11 according to control of the MPU 123.

The MPU 123 performs processing (for example, write processing or read processing) for accessing the NAND memory 11, based on a command transmitted from the host through the HDC 272, according to a first control program. In the present embodiment, for example, the first control program is stored in the ROM 124 in advance.

Instead of the ROM 124, the NAND memory 11, the disk 21, or a rewritable volatile ROM, for example, a flash ROM may be used. A memory area of the RAM 125 is used as a work area of, for example, the MPU 123.

The HDD 20 includes, for example, the disk 21, a head 22, a spindle motor (SPM) 23, an actuator 24, a driver integrated circuit (IC) 25, a head IC 26, and the main controller 27.

The disk 21 includes a recording surface on which data are magnetically recorded, for example, in one surface thereof. The disk 21 is rotated by the SPM 23 at a high speed. The SPM 23 is driven by a drive current (or drive voltage) which is supplied from the driver IC 25.

FIG. 1 illustrates a configuration of the HDD 20 which includes only one disk 21. However, the disk 21 may be an HDD in which multiple disks are stacked. In addition, in the configuration shown in FIG. 1, the disk 21 has a recording surface in one surface thereof. However, the disk 21 may include recording surfaces in both surfaces thereof, and heads may be arranged so as to respectively corresponding to both recording surfaces.

The disk 21 (more specifically, recording surface of the disk 21) has, for example, multiple concentric tracks. Alternatively, the disk 21 may have multiple tracks which are arranged in a spiral shape.

The head (head slider) 22 is arranged so as to correspond to the recording surface of the disk 21. The head 22 is mounted on a tip of a suspension extending from an arm of the actuator 24.

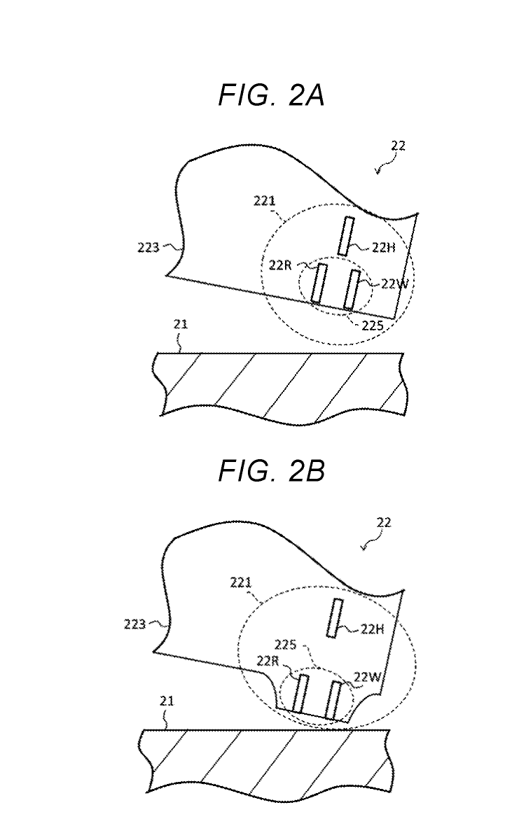

FIG. 2A schematically illustrates the disk 21 and the head 22 in a state in which a heater is not heated. As illustrated in FIG. 2A, the head 22 includes a slider 223 including a head unit 221. Meanwhile, the head 22 (specifically, the head unit 221) includes a heater 22H. FIG. 2A illustrates a state in which the heater 22H does not generate heat.

The head unit 221 includes a read head (also referred to as a read unit or a read element) 22R, a write head (also referred to as a write unit or a write element) 22W, and the heater (also referred to as a heating element) 22H.

The read head 22R reads data recorded on the disk 21. The write head 22W writes data to the disk 21. Meanwhile, the read head 22R and the write head 22W can be collectively referred to as a recording and reproduction element (recording and reproduction unit) 225.

The heater 22H generates heat using received power. As power consumed by the heater 22H increases, temperature of the heater 22H increases (the amount of heat increases).

Meanwhile, in FIGS. 2A and 2B, the single heater 22H is provided in the vicinity of the recording and reproduction element 225, but two heaters may be provided separately in the vicinity of the read head 22R and in the vicinity of the write head 22W, respectively.

FIG. 2B schematically illustrates the disk 21 and the head 22 in a state (when heat is heated) the heater 22H generates heat. As illustrated in FIG. 2B, in a state in which the heater 22H generates heat, the recording and reproduction element 225 of the head unit 221 thermally expands due to the heat of the heater 22H, thereby protruding toward the disk 21. As a result, in a state in which the heater 22H generates heat, the vertex of the recording and reproduction element 225 which is thermally expanded becomes the lowest point of the head 22.

Meanwhile, the amount of protrusion of the head 22 at this time with respect to the disk 21 can be referred to as a protrusion amount. In addition, a distance between the head 22 and the disk 21 can be referred to as flying height amount or clearance. Meanwhile, the sum of the protrusion amount and the flying height amount is approximately constant. In addition, generally, an error is unlikely to occur at a position where a distance between the head 22 and the disk 21 is small, at the time of data writing or data reading.

As described above, since the heater 22H generates heat using power received, the protrusion amount of the head 22 depends upon the amount of power received. In other words, power corresponding to the protrusion amount is supplied (applied) to the heater 22H. Meanwhile, the power which is supplied to the heater 22H is adjusted (changed) according to control information from, for example, the HDC 272. The control information can be referred to as a control value (also referred to as a DAQ value or an instruction value). Hence, the protrusion amount of the head 22 is adjusted according to the control value corresponding to the protrusion amount.

Returning to FIG. 1, the actuator 24 includes a voice coil motor (VCM) 240 which is a drive source of the actuator 24. The VCM 240 is driven by a drive current (or drive voltage) supplied from the driver IC 25. Since the actuator 24 is driven by the VCM 240, the head 22 moves so as to draw an arc in a radial direction of the disk 21 on the disk 21.

The driver IC 25 drives the SPM 23 and the VCM 240 according to the control of the main controller 27 (more specifically, the MPU 123 included in the main controller 27). As the VCM 240 is driven by the driver IC 25, the head 22 is positioned to a target track on the disk 21.

The head IC 26 is also referred to as a head amplifier. For example, the head IC 26 is fixed to a predetermined place around the VCM 240 of the actuator 24, and is electrically connected to the main controller 27 through a flexible printed circuit board (FPCB). However, for the sake of convenience of drawing FIG. 1, the head IC 26 is arranged at a place separated from the actuator 24.

The head IC 26 amplifies a signal (that is, a read signal) which is generated by the read head 22R of the head 22. In addition, the head IC 26 converts write data output from the main controller 27 (more specifically, the R/W channel 271 included in the main controller 27) into a write current, and outputs the write current to the write head 22W of the head 22.

The R/W channel 271 processes signals related to read and write. That is, the R/W channel 271 converts the read signal which is amplified by the head IC 26 into digital data, and decodes read data from the digital data. The R/W channel 271 calculates a value related to an error rate or signal quality, according to the decoded results. Meanwhile, the value related to the signal quality is, for example, VMM, but is not limited to this. In addition, the R/W channel 271 encodes the write data transmitted from the HDC 272, and transmits the encoded write data to the head IC 26.

In addition, the R/W channel 271 functions as a disk interface controller which controls writing of data to the disk 21 and reading of data from the disk 21, through the head IC 26 and the head 22.

The HDC 272 is connected to a host through a host interface (storage interface) 30. The host and the hybrid drive 1 illustrated in FIG. 1 are included in an electronic apparatus such as, a personal computer, a video camera, a music player, a mobile terminal, a mobile phone, or a printer device.

The HDC 272 receives a signal transmitted from the host, and functions as a host interface controller which transmits a signal to the host. Specifically, the HDC 272 receives a command (a write command, a read command, or the like) transmitted from the host, and transmits the received command to the MPU 123. The HDC 272 includes a host IF circuit. In addition, the HDC 272 controls data transmission between the host and the HDC 272.

The MPU 123 controls access to the NAND memory 11 through the memory IF 122, and access to the disk 21 through the R/W channel 271, the head IC 26, and the head 22, according to an access request (write request or read request) from the host. In the present embodiment, a second control program is stored in, for example, the ROM 124, but is not limited to this, and may be stored in the NAND memory 11, the disk 21, a rewritable volatile ROM, or the like. Meanwhile, an initial program loader (IPL) may be stored in the ROM 124, and the second control program may be stored in the disk 21 or the NAND memory 11. In this case, when power is supplied to a hybrid drive, the MPU 123 executes IPL, whereby the second control program may be loaded to the ROM 124 or the RAM 125 from the disk 21 or the NAND memory 11.

The NAND memory 11 has multiple blocks (physical blocks). The NAND memory 11 collectively erases data in units of block. That is, the block is an erasure unit by which data are erased.

Meanwhile, since a minimum unit of writing and a minimum unit of erasure are different from each other in a memory region of the NAND memory 11, it is not possible to erase only partial data from a block and write new data therein. For example, in the NAND memory 11, the minimum unit of writing is one page, and the minimum unit of erasure is one block. For example, one block includes 64 pages, but is not limited thereto.

An erasing operation of the NAND memory 11 is performed in units of block, which includes multiple pages as described above. In addition, a rewriting (overwriting) operation is not completed by one operation, and data writing is performed after erasure. That is, since it is necessary to erase the entirety of one block even by rewriting of one page, at least valid data in the one block is temporarily retained in another memory area.

Multiple non-volatile memory media are mounted in the hybrid drive 1. For example, as multiple NAND memories 11 are provided in the hybrid drive 1, it is possible to prevent the memory area of one NAND memory 11 from being degraded to a certain degree by writing data dispersedly.

Generally, there is a limit in the number of data rewriting to the NAND memory 11. In addition, there is also a limit in a retention period of stored data. As the NAND memory is degraded, the stored data can be lost, when a predetermined period passes. In addition, the retention period of the stored data of the NAND memory 11 is shortened by repeating data rewriting. In addition, it is also known that the retention period of the stored data is shortened in a case where the NAND memory 11 is used under a high-temperature environment.

In addition, the head 22 included in the HDD 20 can change a distance (flying height amount or clearance) between the head 22 and the disk 21 when the recording and reproduction element 225 (refer to FIGS. 2A and 2B) protrudes toward the disk 21 as the heater 22H is heated. This type of control method is referred to as dynamic flying height (DFH) control.

The flying height amount of the head 22 is different in each location of the recording surface of the disk 21. In addition, the flying height amount of the head 22 can differ from each other, in a case where multiple heads and multiple disks are provided. For this reason, the DFH control in which the protrusion amount of the head 22 is optimized may be needed for each head or for each location of the recording surface of the disk.

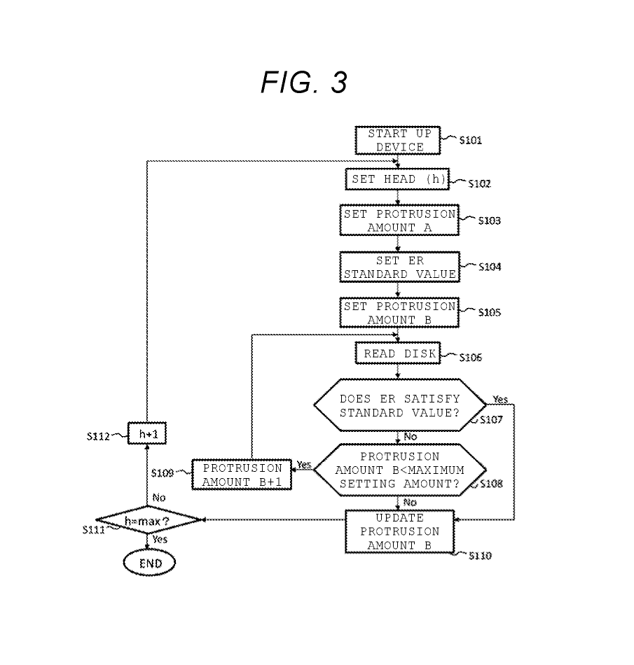

FIG. 3 is a flowchart illustrating an operation for setting the protrusion amount of the head 22 in the hybrid drive 1 according to the present embodiment. Hereinafter, a method for setting the protrusion amount of the head 22 will be described with reference to FIG. 3.

Meanwhile, in the present embodiment, the hybrid drive 1 performs an operation (setting of the protrusion amount of the head 22) according to the flowchart illustrated in FIG. 3, during a predetermined time period after the hybrid drive 1 is started up.

The predetermined time period may be a fixed value (for example, 15 minutes), and, for example, may be appropriately changed depending upon an ambient temperature of the hybrid drive 1.

First, power is supplied to the hybrid drive 1. At this time, in the HDD 20, the disk 21 starts rotating, and the hybrid drive 1 starts up (S101). That is, the HDD 20 starts up.

Subsequently, the HDD 20 set the head 22 as a control target (S102). The HDD 20 can include the disk 21 and the head 22. Here, it is assumed that multiple (for example, N pieces) heads 22 are provided, and the head (h=0) is first set. Meanwhile, h satisfies the relation 0≦h≦N−1.

The HDD 20 sets a protrusion amount A (second protrusion amount) to the head 22 which is set in S102 (S103). Here, the protrusion amount of the head 22 can change depending upon an ambient environment such as temperature or humidity, when the hybrid drive 1 operates. Hence, setting of the protrusion amount A may be performed with reference to temperature profile or the like which is acquired in advance.

As described above, the protrusion amount of the head 22 is adjusted base on amount of power (control value) which is applied to the heater 22H. That is, a control value is set so that the protrusion amount becomes the protrusion amount A.

Subsequently, the HDD 20 sets a standard value (threshold) of quality evaluation index of read data such as an error rate (ER) or a value related to quality of a signal (S104). The error rate indicates an error rate of each data. For example, the error rate indicates a rate of the number of error bits with respect to the number of entire bits of the data. Meanwhile, as described above, the shorter the distance between the head 22 and the disk 21 is, the less the error rate is. In addition, for example, a standard value of the number of error bits may be set rather than the error rate.

The standard value is an allowable value such as an error rate or a value that is related to quality of a signal and obtained during data reading. Hence, the error rate, a value related to the quality of a signal, or the like that satisfies the standard value indicates that the error rate or the value related to the quality of a signal is less than the allowable value, and data can be read correctly. Meanwhile, at least, the standard value may define a boundary of whether or not data, which are a read target, is correctly read.

Thereafter, the HDD 20 sets a protrusion amount B (first protrusion amount) for the head 22 (S105). For example, in S105, the head 22 further protrudes toward the disk 21 by a predetermined amount, as compared with the protrusion amount A which is set in S103. Alternatively, the head 22 can become far apart from the disk 21 by the predetermined amount, with respect to the protrusion amount A which is set in S103. That is, a control value 2 is set so that the protrusion amount becomes the protrusion amount B.

Subsequently, the HDD 20 reads the data recorded in the disk 21 (S106), and determines whether or not an error rate of the read data satisfies the standard value (the predetermined value or the threshold) (S107).

Here, the data read in S106 are, for example, data for evaluation. The data for evaluation are recorded in a predetermined area of the disk 21, for example, a system area, the disk 21, or one place of each of an inner circumference, a medium circumference, and an outer circumference.

If the error rate does not satisfy the standard value (error rate exceeds the threshold) (S107: No), the HDD 20 determines whether or not a control value corresponding to the protrusion amount B reaches a maximum setting value (S108). In other words, in S108, the HDD 20 determines whether or not the protrusion amount B reaches a maximum protrusion amount corresponding to the maximum setting value.

Here, the maximum setting value of the control value at this time corresponds to a protrusion amount when the flying height amount becomes a minimum amount at which the protruded head 22 does not contact the disk 21. The maximum setting value is, for example, a value which is obtained experimentally or by design, or a value which is set based on results of an evaluation test or the like. In addition, in the present embodiment, when the control value corresponding to the protrusion amount of the head 22 reaches the maximum setting value, the protrusion amount of the head 22 equals to the maximum setting amount.

If the control value corresponding to the protrusion amount B does not reach the maximum setting value (the protrusion amount B does not reach the maximum setting amount) (S108: Yes), the HDD 20 increases (for example, “1” is added to the setting value) the protrusion amount B, and reads again the data recorded in the disk 21 (S106). That is, if the error rate does not satisfy the standard value and the control value corresponding to the protrusion amount B is less than the maximum setting value, the head 22 further protrudes and approaches the disk 21.

Meanwhile, if the control value corresponding to the protrusion amount B reaches the maximum setting value (the protrusion amount B reaches the maximum setting amount) (S108: No), or if the error rate satisfies the standard value (S107: Yes), the HDD 20 sets the value of the protrusion amount B as a current value (S110). Thereafter, the HDD 20 determines whether or not h is set as a maximum value (S111). That is, the HDD 20 determines whether or not protrusion values of the entire heads 22 are set.

If h is not set as the maximum value (S111: No), the HDD 20 adds “1” to h, and performs processing of S102 and subsequent processes with respect to another head 22. By the aforementioned processing, the HDD 20 sets the protrusion value for each of the heads 22, during the predetermined time period after start-up thereof. Meanwhile, the respective parameters such as, the protrusion amount A, the protrusion amount B, the standard value of an error rate, and h are stored in a non-volatile memory unit (for example, the NAND memory 11, the disk 21, the ROM 124, or the like) as management information, and are read into the RAM 125 during the operation.

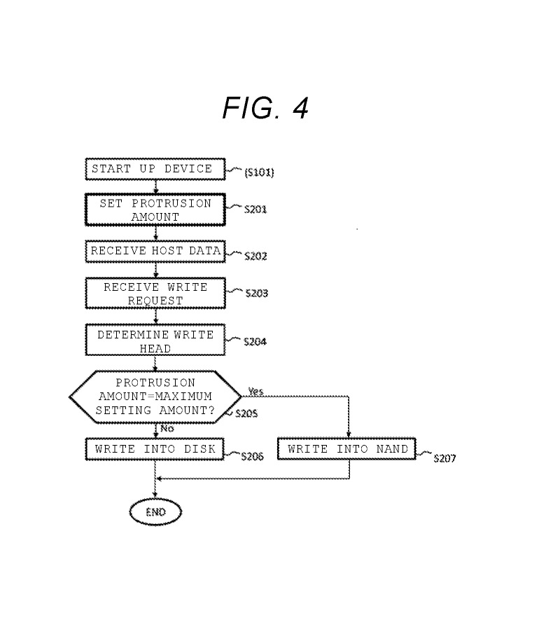

Next, an operation at the time of data writing processing of the hybrid drive 1 will be described with reference to FIG. 4. FIG. 4 is a flowchart illustrating a processing operation at the time of data writing of the hybrid drive 1 according to the present embodiment.

First, the hybrid drive 1 starts up (S101), and the protrusion amount of the head 22 is set (S201). Meanwhile, in S201, the protrusion amount of the head 22 is set according to the flowchart illustrated in FIG. 3. Here, detailed description thereof will be omitted.

When the hybrid drive 1 receives a command and data (data for writing) from a host through the host interface 30 (S202), the MPU 123 instructs, for example, the R/W channel 271 to send a write request. After the R/W channel 271 receives the write request (S203), the R/W channel 271 determines (selects) the head 22 (write head 22W) to be used for writing (S204). Here, the head 22 which is determined to be used for writing is also referred to as a candidate head 22. Meanwhile, the protrusion amount of each of multiple heads 22 is set in S201 in advance.

In S204, the setting of the head 22 may designated by a write command that is received from, for example, the host.

Subsequently, the hybrid drive 1 determines whether or not the protrusion amount of the candidate head 22 is a maximum setting amount (S205). If the protrusion amount of the head 22 is not the maximum setting amount (S205: No), the data received from the host are written to the disk 21 (S206). Meanwhile, if the protrusion amount of the head 22 is the maximum setting amount (S205: Yes), the data received from the host are written to the NAND memory 11 (S207).

As described above, according to the present embodiment, the hybrid drive 1 dividedly writes data received from the host into the disk 21 and the NAND memory 11, respectively, according to the protrusion amount of the head 22 during the predetermined time period after start-up thereof.

As described above, the storage device 1 such as the aforementioned hybrid drive 1 may sometimes have undesirable write characteristics during the predetermined time after start-up thereof, and a write error is more likely to occur (error rate easily increases).

In the present embodiment, if the error rate does not satisfy the standard value (the error rate exceeds the threshold), the hybrid drive 1 causes the head 22 to protrude by a predetermined amount. Accordingly, it is possible to reduce the error rate.

Meanwhile, since it is not preferable that the disk 21 contacts the head 22 during data writing, there is an upper limit (maximum setting amount) in the protrusion amount of the head 22. In addition, as described in the flowchart illustrated in FIG. 3, if the protrusion amount of the head 22 becomes the maximum setting amount, there is a possibility that the error rate does not satisfy the standard value.

In the present embodiment, if the protrusion amount of the head 22 adjusted during the predetermined time period after the hybrid drive 1 starts up is the maximum setting amount, the hybrid drive 1 writes the write data received from the host into the NAND memory 11. Accordingly, even if there is great possibility that the error rate increases due to data writing to the disk 21, it is possible to correctly write data.

In addition, in the present embodiment, a write operation to the NAND memory 11 is performed, if the protrusion amount of the head 22 adjusted during the predetermined time period after the hybrid drive 1 starts up is the maximum setting amount. For that reason, it is possible that the hybrid drive 1 can reduce writing to the NAND memory 11 having an upper limit as the number of writing, and can perform a write operation with a smaller error rate and higher reliability.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A storage device, comprising:
a disk;
a head configured to carry out data writing and data reading with respect to the disk, and including a heater that generates heat to cause the head to thermally expand towards the disk;
a non-volatile semiconductor memory; and
a controller configured to set an amount of expansion of the head, based on data read from the disk during a predetermined period of time after the storage device has been turned on, and selectively write data from a host in the disk or the non-volatile semiconductor memory during the predetermined period of time, based on the amount of expansion.

2. The storage device according to claim 1, wherein
when the amount of expansion is a maximum settable amount, the controller writes the data from the host in the non-volatile semiconductor memory, and
when the amount of expansion is less than the maximum settable amount, the controller writes the data from the host in the disk.

3. The storage device according to claim 1, wherein
when the data read from the disk during the predetermined period of time include errors in excess of a predetermined threshold, the amount of expansion of the head is increased.

4. The storage device according to claim 3, wherein
the predetermined threshold is a predetermined error rate or a predetermined number of error bits.

5. The storage device according to claim 1, wherein
when the data read from the disk during the predetermined period of time include no error or an error less than a predetermined threshold, a current amount of expansion of the head is set as the amount of expansion.

6. The storage device according to claim 5, wherein
the predetermined threshold is a predetermined error rate or a predetermined number of error bits.

7. The storage device according to claim 1, wherein
the controller sets the amount of expansion of the head by driving the heater with power corresponding thereto.

8. A storage device, comprising:
a plurality of disks;
a plurality of heads, each of the heads corresponding to one of the disks and configured to carry out data writing and data reading with respect to the corresponding disk, and including a heater that generates heat to cause the head to thermally expand towards the corresponding disk;
a non-volatile semiconductor memory; and
a controller configured to set an amount of protrusion of each of the heads, based on data read from the corresponding disk during a predetermined period of time after the storage device has been turned on, selectively write data from a host in one of the disks or the non-volatile semiconductor memory, based on the amount of protrusion corresponding to said one of the disks.

9. The storage device according to claim 8, wherein
the controller writes the data from the host in said one of the disks based on a command received from a host.

10. The storage device according to claim 8, wherein
when the amount of protrusion corresponding to said one of the disks is a maximum settable amount, the controller writes the data in the non-volatile semiconductor memory, and
when the amount of protrusion corresponding to said one of the disks is less than the maximum settable amount, the controller writes the data in said one of the disks.

11. The storage device according to claim 8, wherein
when the data read from each of the disks during the predetermined period of time include errors in excess of a predetermined threshold, the amount of protrusion of the corresponding head is increased.

12. The storage device according to claim 11, wherein
the predetermined threshold is a predetermined error rate or a predetermined number of error bits.

13. The storage device according to claim 8, wherein
when the data read from each of the disks during the predetermined period of time include no error or an error less than a predetermined threshold, a current amount of protrusion of the corresponding head is set as the amount of protrusion thereof.

14. The storage device according to claim 13, wherein
the predetermined threshold is a predetermined error rate or a predetermined number of error bits.

15. The storage device according to claim 8, wherein
the controller sets the amount of protrusion of each of the heads by driving the heater thereof with power corresponding thereto.

16. A method for operating a storage device including a disk, a head including a heater that generates heat to cause the head to thermally expand towards the disk, and a non-volatile semiconductor memory, the method comprising:
reading data from the disk during a predetermined period of time after the storage device has been turned on;
setting an amount of expansion of the head based on the read data; and
selectively writing data in the disk or the non-volatile semiconductor memory during the predetermined period of time, based on the amount of expansion.

17. The method according to claim 16, wherein
when the amount of expansion is a maximum settable amount, the data are written in the non-volatile semiconductor memory, and
when the amount of expansion is less than the maximum settable amount, the data are written in the disk.

18. The method according to claim 16, wherein
when the read data include errors in excess of a predetermined threshold, the amount of expansion of the head is increased in the setting.

19. The method according to claim 16, wherein
when the read data include no error or an error less than a predetermined threshold, a current amount of expansion of the head is set as the amount of expansion in the setting.

20. The method according to claim 16, wherein
the amount of expansion of the head is set by driving the heater with power corresponding thereto.
